(19) United States
(12) Patent Application Publication
(10) Pub. No.: US 2025/0169207 A1
(43) Pub. Date: May 22, 2025

(54) IMAGE SENSING DEVICE

(71) Applicant: SK hynix Inc., Icheon-si (KR)

(72) Inventors: Hyun Soo LIM, Icheon-si (KR); Hee Dong KIM, Icheon-si (KR); Sung Ho CHOI, Icheon-si (KR)

(21) Appl. No.: 18/947,658

(22) Filed: Nov. 14, 2024

(30) Foreign Application Priority Data
Nov. 17, 2023 (KR) 10-2023-0159812

(51) Int. Cl. H01L 27/146; H04N 25/77

(52) U.S. Cl. CPC H10F 39/8027; H04N 25/77; H10F 39/8063; H10F 39/811

(57) ABSTRACT

An image sensing device includes a first photoelectric conversion element configured to overlap a left region of a first microlens, a second photoelectric conversion element configured to overlap a right region of the first microlens, a first floating diffusion region configured to accumulate photocharges received from at least one of the first photoelectric conversion element and the second photoelectric conversion element, a first transfer gate disposed at a top-left side of the first floating diffusion region and configured to transfer photocharges of the first photoelectric conversion element to the first floating diffusion region, and a second transfer gate disposed at a bottom-right side of the first floating diffusion region and configured to transfer photocharges of the second photoelectric conversion element to the first floating diffusion region.

### CROSS-REFERENCE TO RELATED APPLICATION

This patent document claims the priority and benefits of Korean patent application No. 10-2023-0159812, filed on Nov. 17, 2023, the disclosure of which is incorporated herein by reference in its entirety as part of the disclosure of this patent document.

### TECHNICAL FIELD

The technology and implementations disclosed in this patent document generally relate to an image sensing device capable of generating image data by sensing light.

### BACKGROUND

An image sensing device is a device for capturing optical images by converting light into electrical signals using a photosensitive semiconductor material which reacts to light. With the development of automotive, medical, computer and communication industries, the demand for high-performance image sensing devices is increasing in various fields such as smart phones, digital cameras, game machines, IoT (Internet of Things), robots, security cameras and medical micro cameras.

The image sensing device may be roughly divided into CCD (Charge Coupled Device) image sensing devices and CMOS (Complementary Metal Oxide Semiconductor) image sensing devices. The CCD image sensing devices offer a better image quality, but they tend to consume more power and are larger as compared to the CMOS image sensing devices. The CMOS image sensing devices are smaller in size and consume less power than the CCD image sensing devices. Furthermore, CMOS sensors are fabricated using the CMOS fabrication technology, and thus photosensitive elements and other signal processing circuitry can be integrated into a single chip, enabling the production of miniaturized image sensing devices at a lower cost. For these reasons, CMOS image sensing devices are being developed for many applications including mobile devices.

### SUMMARY

In accordance with an embodiment of the disclosed technology, an image sensing device may include: a first photoelectric conversion element configured to generate photocharges in response to an incident light and disposed to overlap a first region of a first microlens; a second photoelectric conversion element configured to generate photocharges in response to the incident light and disposed to overlap a second region of the first microlens, wherein the first region and the second region are disposed along a first direction; a first floating diffusion region located adjacent to the first photoelectric conversion element and the second photoelectric conversion element; a first transfer gate disposed at a first side of the first floating diffusion region and configured to transfer the photocharges generated by the first photoelectric conversion element to the first floating diffusion region; and a second transfer gate disposed at a second side of the first floating diffusion region and configured to transfer the photocharges generated by the second photoelectric conversion element to the first floating diffusion region, the second side being apart from the first side along the first direction and a second direction perpendicular to the first direction.

In accordance with another embodiment of the disclosed technology, an image sensing device may include a first pixel group configured to include a first microlens, a first photoelectric conversion element overlapping a left region of the first microlens and configured to convert light incident to the first photoelectric conversion element into photocharges, and a second photoelectric conversion element overlapping a right region of the first microlens and configured to convert light incident to the second photoelectric conversion element into photocharges, and a first transfer gate located at a first position with respect to a center of the first pixel group and configured to transfer the photocharges generated by the first photoelectric conversion element to a first floating diffusion region of the first pixel group; and a second pixel group configured to include a second microlens, a third photoelectric conversion element overlapping an upper region of the second microlens and configured to convert light incident to the third photoelectric conversion element into photocharges, and a fourth photoelectric conversion element overlapping a lower region of the second microlens and configured to convert light incident to the fourth photoelectric conversion element into photocharges, and a second transfer gate located at the first position with respect to the center of the second pixel group and configured to transfer the photocharges generated by the third photoelectric conversion element to a second floating diffusion region of the second pixel group.

In accordance with another embodiment of the disclosed technology, an image sensing device may include a first photoelectric conversion element configured to generate photocharges in response to an incident light and disposed to overlap an upper region of a first microlens; a second photoelectric conversion element configured to generate photocharges in response to the incident light and disposed to overlap a lower region of the first microlens; a floating diffusion region configured to accumulate photocharges received from at least one of the first photoelectric conversion element or the second photoelectric conversion element; a first transfer gate disposed at a top-left side of the floating diffusion region and configured to transfer the photocharges generated by the first photoelectric conversion element to the floating diffusion region; and a second transfer gate disposed at a bottom-right side of the floating diffusion region and configured to transfer the photocharges generated by the second photoelectric conversion element to the floating diffusion region.

### BRIEF DESCRIPTION OF THE DRAWINGS

The above and other features and beneficial aspects of the disclosed technology will become readily apparent with reference to the following detailed description when considered in conjunction with the accompanying drawings.

FIG. 1 is a block diagram illustrating an example of an imaging device based on some implementations of the disclosed technology.

FIG. 2 is a diagram illustrating an example of a portion of a pixel array based on some implementations of the disclosed technology.

FIG. 3 is a circuit diagram illustrating an example of an equivalent circuit for four pixel groups shown in FIG. 2 based on some implementations of the disclosed technology.

FIG. 4 is a diagram illustrating an example of a layout structure of elements included in a shared pixel structure shown in FIG. 3 based on some implementations of the disclosed technology.

FIG. 5 is a diagram illustrating another example of the layout structure of elements included in the shared pixel structure shown in FIG. 3 based on some implementations of the disclosed technology.

FIG. 6A is a detailed diagram illustrating an example of a layout structure for a first pixel group shown in FIG. 4 based on some implementations of the disclosed technology.

FIG. 6B is a detailed diagram illustrating an example of a layout structure for a fifth pixel group shown in FIG. 4 based on some implementations of the disclosed technology.

FIG. 7A is a detailed diagram illustrating another example of a layout structure for a first pixel group shown in FIG. 5 based on some implementations of the disclosed technology.

FIG. 7B is a detailed diagram illustrating another example of a layout structure for a fifth pixel group shown in FIG. 5 based on some implementations of the disclosed technology.

FIG. 8 is a cross-sectional view illustrating an example of pixel groups shown in FIGS. 6A to 7B based on some implementations of the disclosed technology.

FIGS. 9A and 9B are diagrams illustrating examples of functions of a charge overflow barrier based on some implementations of the disclosed technology.

### DETAILED DESCRIPTION

This patent document provides implementations and examples of an image sensing device capable of generating image data by sensing light that may be used in configurations to substantially address one or more technical or engineering issues and to mitigate limitations or disadvantages encountered in some other image sensing devices. Some implementations of the disclosed technology relate to an image sensing device configured to have an autofocus function. In recognition of the issues above, the disclosed technology may provide the image sensing device in which transfer gates included in each pixel group corresponding to one microlens are arranged symmetrically to each other with respect to the center of the pixel group, thereby guaranteeing symmetry between pixel groups affecting signal characteristics.

Reference will now be made in detail to the embodiments of the disclosed technology, examples of which are illustrated in the accompanying drawings. Wherever possible, the same reference numbers will be used throughout the drawings to refer to the same or like parts. While the disclosure is susceptible to various modifications and alternative forms, specific embodiments thereof are shown by way of example in the drawings. However, the disclosure should not be construed as being limited to the embodiments set forth herein.

Hereinafter, various embodiments will be described with reference to the accompanying drawings. However, it should be understood that the disclosed technology is not limited to specific embodiments, but includes various modifications, equivalents and/or alternatives of the embodiments. The embodiments of the disclosed technology may provide a variety of effects capable of being directly or indirectly recognized through the disclosed technology.

Various embodiments of the disclosed technology relate to an image sensing device configured to perform an autofocus function.

It is to be understood that both the foregoing general description and the following detailed description of the disclosed technology are illustrative and explanatory and are intended to provide further explanation of the disclosure as claimed.

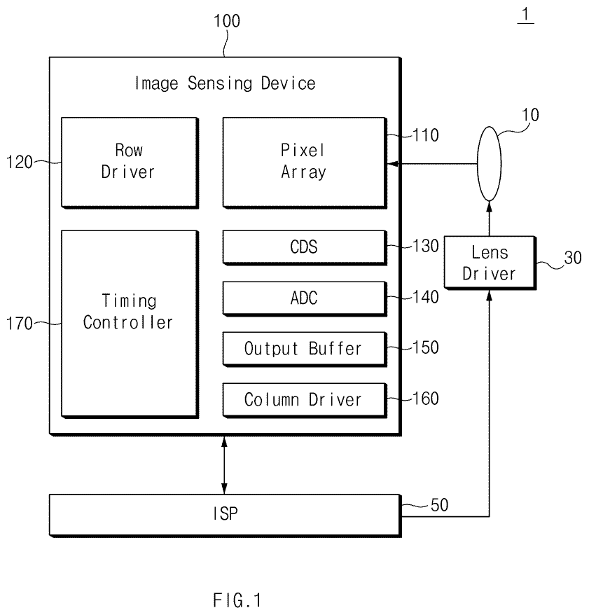

FIG. 1 is a block diagram illustrating an example of an imaging device 1 based on some implementations of the disclosed technology.

Referring to FIG. 1, the imaging device 1 may refer to a device, for example, a digital still camera for photographing still images or a digital video camera for photographing moving images. For example, the imaging device 1 may be implemented as a Digital Single Lens Reflex (DSLR) camera, a mirrorless camera, or a smartphone, and others. The imaging device 1 may include a device having both a lens and an image pickup element such that the device can capture (or photograph) a target object and can thus create an image of the target object.

The imaging device 1 may include a lens 10, a lens driver 30, an image sensing device 100, and an image signal processor (ISP) 50.

The lens 10 is provided to collect light to be captured by the image sensing device 100 and may include at least one lens aligned with respect to an optical axis. The lens 10 may be disposed in front of the image sensing device 100 to transmit an optical signal to the image sensing device 100, and the position of the lens 10 may be adjusted by the lens driver 30. For example, the lens 10 may move along the optical axis by the lens driver 30. The optical signal transmitted through the lens 10 may be incident upon a light reception surface of the image sensing device 100 to form an image of a subject.

The lens driver 30 may adjust the position of the lens 10 according to a control signal received from the image signal processor 50. The lens driver 30 may adjust the position of the lens 10 to perform various operations such as autofocus, zoom change, etc.

The image sensing device 100 may be a complementary metal oxide semiconductor image sensor (CIS) for converting an optical signal into an electrical signal. The image sensing device 100 may adjust or regulate on/off operations, an operation mode, sensitivity, etc. by the image signal processor 50.

The image sensing device 100 may include a pixel array 110, a row driver 120, a correlated double sampler (CDS) 130, an analog-to-digital converter (ADC) 140, an output buffer 150, a column driver 160, and a timing controller 170. The components of the image sensing device 100 illustrated in FIG. 1 are discussed by way of example only, and this patent document encompasses numerous other changes, substitutions, variations, alterations, and modifications.

The pixel array 110 may include a plurality of imaging pixels arranged in rows and columns. In one example, the plurality of imaging pixels can be arranged in a two-dimensional (2D) pixel array including rows and columns. In another example, the plurality of imaging pixels can be arranged in a three-dimensional (3D) pixel array. The plurality of imaging pixels may convert an optical signal into an electrical signal on a unit pixel basis or a pixel group basis, where pixels in a pixel group share at least certain internal circuitry. The pixel array 110 may receive driving signals, including a row selection signal, a pixel reset signal and a transfer signal, from the row driver 120. Upon receiving the driving signal, corresponding imaging pixels in the pixel array 110 may be activated to perform the operations corresponding to the row selection signal, the pixel reset signal, and the transfer signal.

The row driver 120 may activate the pixel array 110 to perform certain operations on the imaging pixels in the corresponding row based on commands and control signals provided by controller circuitry such as the timing controller 170. In some implementations, the row driver 120 may select one or more imaging pixels arranged in one or more rows of the pixel array 110. The row driver 120 may generate a row selection signal to select one or more rows among the plurality of rows. The row driver 120 may sequentially enable the pixel reset signal for resetting imaging pixels corresponding to at least one selected row, and the transfer signal for the pixels corresponding to the at least one selected row. Thus, a reference signal and an image signal, which are analog signals generated by each of the imaging pixels of the selected row, may be sequentially transferred to the CDS 130. The reference signal may be an electrical signal that is provided to the CDS 130 when a sensing node of an imaging pixel (e.g., floating diffusion node) is reset, and the image signal may be an electrical signal that is provided to the CDS 130 when photocharges generated by the imaging pixel are accumulated in the sensing node. The reference signal indicating unique reset noise of each pixel and the image signal indicating the intensity of incident light may be generically called a pixel signal as necessary.

CMOS image sensors may use correlated double sampling (CDS) to remove undesired offset values of pixels known as the fixed pattern noise by sampling a pixel signal twice to remove the difference between these two samples. In one example, the correlated double sampling (CDS) may remove the undesired offset value of pixels by comparing pixel output voltages obtained before and after photocharges generated by incident light are accumulated in the sensing node so that only pixel output voltages based on the incident light can be measured. In some embodiments of the disclosed technology, the correlated double sampling (CDS) 130 may sequentially sample and hold voltage levels of the reference signal and the image signal, which are provided to each of a plurality of column lines from the pixel array 110. That is, the correlated double sampling (CDS) 130 may sample and hold the voltage levels of the reference signal and the image signal which correspond to each of the columns of the pixel array 110.

In some implementations, the CDS 130 may transfer the reference signal and the image signal of each of the columns as a correlate double sampling signal to the ADC 140 based on control signals from the timing controller 170.

The ADC 140 is used to convert analog CDS signals into digital signals. In some implementations, the ADC 140 may be implemented as a ramp-compare type ADC. The ramp-compare type ADC may include a comparator circuit for comparing the analog pixel signal with a reference signal such as a ramp signal that ramps up or down, and a timer (or counter) for performing counting until a voltage of the ramp signal matches the analog pixel signal. In some embodiments of the disclosed technology, the ADC 140 may convert the correlate double sampling signal generated by the CDS 130 for each of the columns into a digital signal, and output the digital signal. The ADC 140 may perform a counting operation and a computing operation based on the correlate double sampling signal for each of the columns and a ramp signal provided from the timing controller 170. In this way, the ADC 140 may eliminate or reduce noises such as reset noise arising from the imaging pixels when generating digital image data.

The ADC 140 may include a plurality of column counters corresponding to the respective columns. Each column of the pixel array 110 may be coupled to a column counter, and image data may be generated by converting the correlate double sampling (CDS) signals received from each column into digital signals using the column counter. In another embodiment of the disclosed technology, the ADC 140 may include a global counter to convert the correlate double sampling (CDS) signals corresponding to the columns into digital signals using a global code provided from the global counter. In this case, the image data may refer to a digital signal generated through conversion of a pixel signal output from at least one image pixel.

The output buffer 150 may temporarily hold the column-based image data provided from the ADC 140 to output the image data. In one example, the image data provided to the output buffer 150 from the ADC 140 may be temporarily stored in the output buffer 150 based on control signals of the timing controller 170. The output buffer 150 may provide an interface to compensate for data rate differences or transmission rate differences between the image sensing device 100 and other devices.

The column driver 160 may select a column of the output buffer 150 upon receiving a control signal from the timing controller 170, and sequentially output the image data temporarily stored in the selected column of the output buffer 150. In some implementations, upon receiving an address signal from the timing controller 170, the column driver 160 may generate a column selection signal based on the address signal and select a column of the output buffer 150, so that the image data as output signals from the selected column of the output buffer 150 can be output to the image signal processor 50.

The timing controller 170 may control at least one of the row driver 120, the CDS 130, the ADC 140, the output buffer 150, and the column driver 160.

The timing controller 170 may provide the row driver 120, the CDS 130, the ADC 140, the output buffer 150, and the column driver 160 with a clock signal required for the operations of the respective components of the image sensing device 100, a control signal for timing control, and address signals for selecting a row or column. In an embodiment of the disclosed technology, the timing controller 170 may include a logic control circuit, a phase lock loop (PLL) circuit, a timing control circuit, a communication interface circuit and others.

The image signal processor (ISP) 50 may perform image processing of image data received from the image sensing device 100, and may control each component of the imaging device 1 according to the processed result or external input signals. The image signal processor (ISP) 50 may reduce noise of image data, and may perform various kinds of image signal processing (e.g. gamma correction, color filter array interpolation, color matrix, color correction, color enhancement, etc.) for image-quality improvement of the image data. In addition, the image signal processor (ISP) 50 may compress image data that has been created by execution of image signal processing for image-quality improvement, such that the image signal processor (ISP) 50 can create an image file using the compressed image data. Alternatively, the image signal processor (ISP) 50 may recover image data from the image file. In this case, the scheme for compressing such image data may be a reversible format or an irreversible format. As a representative example of such compression format, in the case of using a still image, Joint Photographic Experts Group (JPEG) format, JPEG 2000 format, or the like can be used. In addition, in the case of using moving images, a plurality of frames can be compressed according to Moving Picture Experts Group (MPEG) standards such that moving image files can be created. For example, the image files may be created according to Exchangeable image file format (Exif) standards.

The image data generated from the image signal processor 50 may be stored in an internal memory of the imaging device 1 or an external memory either in response to a user request or in an automatic manner, such that the stored image data can be displayed through a display.

In addition, the image signal processor 50 may perform unclearness processing, blur processing, edge emphasis processing, image analysis processing, image recognition processing, image effect processing, or others.

In addition, the image signal processor 50 may perform display image signal processing for the display. For example, the image signal processor 50 may perform brightness level adjustment, color correction, contrast adjustment, outline emphasis adjustment, screen division processing, character image generation, and image synthesis processing, or others.

The image signal processor 50 may control the lens driver 30, the aperture driver 40, and the image sensing device 100 according to a control signal that is automatically generated by an image signal being input in real time or a control signal manually input by a user.

For example, the image signal processor 50 may detect a focus of an image based on image data received from the image sensing device 100. The image signal processor 50 may compare different types of image data with each other, may perform a correlation operation based on a result of the comparison, and may thus calculate a defocus value based on a result of the correlation operation.

In the example, image data generated by the image sensing device 100 may include first to fourth phase data. The first to fourth phase data may be data generated by the first to fourth phase difference detection pixels, respectively. In more detail, the first phase data may be data generated by the first phase difference detection pixel, the second phase data may be data generated by the second phase difference detection pixel, the third phase data may be data generated by the third phase difference detection pixel, and the fourth phase data may be data generated by the fourth phase difference detection pixel.

The first phase difference detection pixel may be a pixel that overlaps a left hemisphere (or a left region) of the microlens, and the second phase difference detection pixel may be a pixel that overlaps a right hemisphere (or a right region) of the microlens. Thus, the first phase difference detection pixel and the second phase difference detection pixel may overlap different regions of one microlens to form one first paired pixel group.

A set of first phase data generated by a plurality of first phase difference detection pixels included in the pixel array 110 may constitute a first phase frame, and a set of second phase data generated by a plurality of second phase difference detection pixels included in the pixel array 110 may constitute a second phase frame. The image signal processor 50 may calculate a first pixel shift value that minimizes the sum of absolute difference (SAD) between a first phase frame and a second phase frame. Here, the first pixel shift value may be a value indicating how far images corresponding to the first phase difference detection pixels and images corresponding to the second phase difference detection pixels are shifted to the left or right about the optical axis.

The third phase difference detection pixel may be a pixel that overlaps an upper hemisphere (or an upper region) of the microlens, and the fourth phase difference detection pixel may be a pixel that overlaps a lower hemisphere (or a lower region) of the microlens. Thus, the third phase difference detection pixel and the fourth phase difference detection pixel may overlap different regions of one microlens to form one second paired pixel group.

A set of third phase data generated by a plurality of third phase difference detection pixels included in the pixel array 110 may constitute a third phase frame, and a set of fourth phase data generated by a plurality of fourth phase difference detection pixels included in the pixel array 110 may constitute a fourth phase frame. The image signal processor 50 may calculate a second pixel shift value that minimizes a correlation calculation value between a third phase frame and a fourth phase frame. Here, the second pixel shift value may be a value indicating how far images corresponding to the third phase difference detection pixels and images corresponding to the fourth phase difference detection pixels are shifted to up or down about the optical axis.

The image signal processor 50 may calculate a pixel shift result using the first pixel shift value and the second pixel shift value. In some implementations, the image signal processor 50 may calculate an average value of the first pixel shift value and the second pixel shift value, and may determine the calculated average value as a pixel shift result. In some other implementations, the image signal processor 50 may determine one of the first pixel shift value and the second pixel shift value as a pixel shift result. In some other implementations, the image signal processor 50 may determine a pixel shift result by applying and adding a predetermined weight to each of the first pixel shift value and the second pixel shift value.

The image signal processor 50 may calculate a defocus value corresponding to the pixel shift result by referring to a table. In the table, the pixel shift result and the defocus value are mapped to each other. Such table may be prestored in the image signal processor 50. The defocus value may be a control value that can control the lens driver 30 to adjust a focal distance. The lens driver 30 may move the lens 10 to a position corresponding to the defocus value received from the image signal processor 50, so that the image of the subject can be focused on a light reception surface of the image sensing device 100 (i.e., an in-focus state).

According to the disclosed technology, the focus may be adjusted more accurately and appropriately by using not only the first pixel shift value representing a phase difference in a horizontal direction but also the second pixel shift value representing a phase difference in a vertical direction.

In some implementations, the image signal processor 50 may generate color image data for the first paired pixel group by summing the first and second phase data of the first and second phase difference detection pixels corresponding to one microlens, and may generate color image data for the second paired pixel group by summing the third and fourth phase data of the third and fourth phase difference detection pixels corresponding to one microlens. The image signal processor 50 may obtain a color image for a scene by using color image data for the first paired pixel group and color image data for the second paired pixel group.

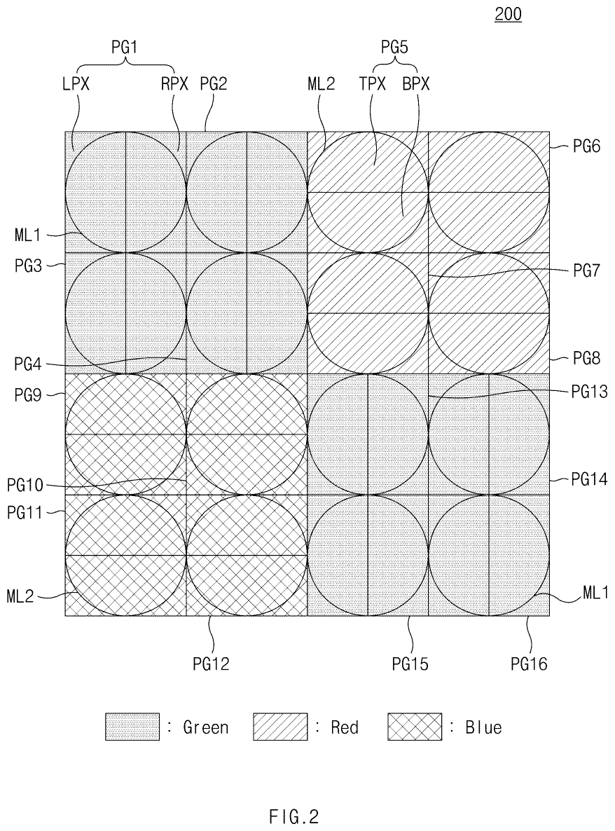

FIG. 2 is a diagram illustrating an example of a portion of the pixel array 110 of an array of photoelectric conversion elements or photodetectors PDs based on some implementations of the disclosed technology.

Referring to FIG. 2, an example portion 200 of the pixel array 110 is shown. The pixel array 110 may have a structure in which the example portion 200 of the pixel array 110 is repeatedly arranged in row and column directions, but the scope of the disclosed technology is not limited thereto.

The example portion 200 of the pixel array 110 may include first to sixteenth pixel groups (PG1˜PG16). Each of the first to fourth pixel groups (PG1˜PG4) and the thirteenth to sixteenth pixel groups (PG13˜PG16) may correspond to the first paired pixel group described in FIG. 1. Each of the fifth to twelfth pixel groups (PG5˜PG12) may correspond to the second paired pixel group described in FIG. 1.

The pixel array 110 may be structured to include a layer of color filters to filter incident light collected by the lens 10 before captured by the pixels in the pixel array 110 to provide color information of the captured image in the incident light. Various color filter designs may be implemented, including, for example, a Bayer filter which is a color filter array for arranging red (R), green (G) and blue (B) color filters respectively placed on individual photoelectric elements, photosensors or photodetectors PDs with 50% green color filters, 25% red color filters, and 25% blue color filters. In the example shown in FIG. 2, the different pixel groups are respectively matched with different color filters with the photoelectric conversion elements within each pixel group being covered with color filters of a common color for that pixel group. As illustrated, each of the first to fourth pixel groups (PG1˜PG4) may include a green color filter that selectively transmits green light, and may include green pixels that detect green light. The first to fourth pixel groups (PG1˜PG4) may be arranged in a (2×2) matrix structure. Each of the first to fourth pixel groups (PG1˜PG4) may include a first phase difference detection pixel (LPX) and a second phase difference detection pixel (RPX) that overlap a first microlens (ML1). In other implementations of the disclosed technology, color filters based on other color filter designs other than the Bayer filter array may also be used.

Each of the fifth to eighth pixel groups (PG5˜PG8) may include a red color filter that selectively transmits red light, and may include red pixels that detect red light. The fifth to eighth pixel groups (PG5˜PG8) may be arranged in a (2×2) matrix structure. Each of the fifth to eighth pixel groups (PG5˜PG8) may include a third phase difference detection pixel (TPX) and a fourth phase difference detection pixel (BPX) that overlap a second microlens (ML2).

Each of the ninth to twelfth pixel groups (PG9˜PG12) may include a blue color filter that selectively transmits blue light, and may include blue pixels that detect blue light. The ninth to twelfth pixel groups (PG9˜PG12) may be arranged in a (2×2) matrix structure. Each of the ninth to twelfth pixel groups (PG9˜PG12) may include a third phase difference detection pixel (TPX) and a fourth phase difference detection pixel (BPX) that overlap a second microlens (ML2).

Each of the thirteenth to sixteenth pixel groups (PG13˜PG16) may include a green color filter that selectively transmits green light, and may include green pixels that detect green light. The thirteenth to sixteenth pixel groups (PG13˜PG16) may be arranged in a (2×2) matrix structure. Each of the thirteenth to sixteenth pixel groups (PG13˜PG16) may include a first phase difference detection pixel (LPX) and a second phase difference detection pixel (RPX) that overlap a first microlens ML1.

The first to fourth pixel groups (PG1˜PG4) and the thirteenth to sixteenth pixel groups (PG13˜PG16) corresponding to green pixels, the fifth to eighth pixel groups (PG5˜PG8) corresponding to red pixels, and the ninth to twelfth pixel groups (PG9˜PG12) corresponding to blue pixels may be arranged in a Bayer pattern as a whole.

In some implementations, each of the pixel groups (PG1˜PG16) may be formed in a square shape and each of the phase difference detection pixels (LPX, RPX, TPX, BPX) may be formed in a rectangular shape having a preset area corresponding to a half of the area of each pixel group (PG1˜PG16), but the scope of the disclosed technology is not limited thereto.

In addition, arrangement of the pixel groups (PG1˜PG16) illustrated in FIG. 2 is merely an example, and other implementations are possible. For example, in another implementation, four pixel groups instead of 16 pixel groups may constitute a Bayer pattern.

In some implementations, each of the first to fourth pixel groups (PG1˜PG4) and the thirteenth to sixteenth pixel groups (PG13˜PG16) may correspond to the first paired pixel group described in FIG. 2, and each of the fifth to eighth pixel groups (PG5˜PG8) and the ninth to twelfth pixel groups (PG9˜PG12) may correspond to the second paired pixel group described in FIG. 2.

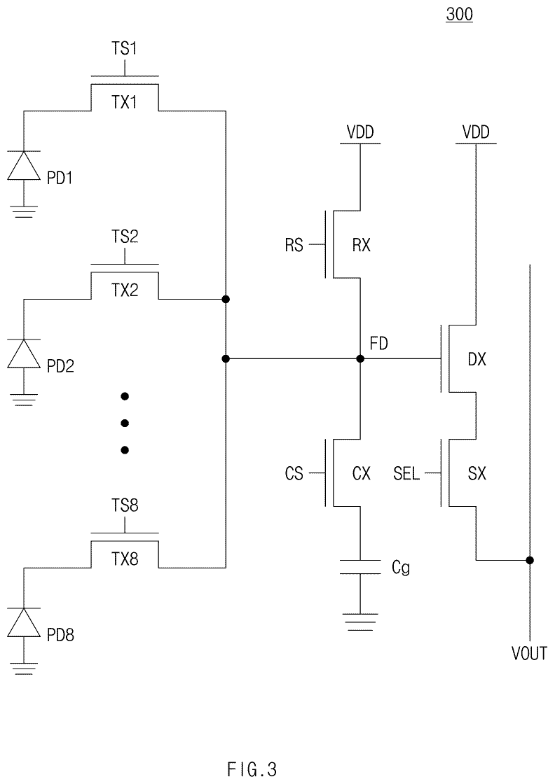

FIG. 3 is a circuit diagram illustrating an example of an equivalent circuit for the four pixel groups shown in FIG. 2 based on some implementations of the disclosed technology.

Referring to FIG. 3, the first to fourth pixel groups (PG1˜PG4) may be implemented as a shared pixel structure as a unit of four pixel groups, the fifth to eighth pixel groups (PG5˜PG8) may be implemented as a shared pixel structure as a unit of four pixel groups, the ninth to twelfth pixel groups (PG9˜PG12) may be implemented as a shared pixel structure as a unit of four pixel groups, and the thirteenth to sixteenth pixel groups (PG13˜PG16) may be implemented as a shared pixel structure as a unit of four pixel groups. Here, the shared pixel structure may mean a structure in which a plurality of phase difference detection pixels shares at least one element.

In the disclosed technology, the following description will focus on an embodiment in which 8 phase difference detection pixels included in four pixel groups are implemented as a shared pixel structure. However, the scope of the disclosed technology is not limited thereto. For example, different suitable numbers of phase difference detection pixels (e.g., 4 phase difference detection pixels) may be designed to have a shared pixel structure. In some implementations, for example, each phase difference detection pixel may have an independent structure.

The shared pixel structure 300 shown in FIG. 3 may correspond to one of the first to fourth pixel groups (PG1˜PG4), the fifth to eighth pixel groups (PG5˜PG8), the ninth to twelfth pixel groups (PG9˜PG12), or the thirteenth to sixteenth pixel groups (PG13˜PG16).

For example, the shared pixel structure 300 may include first to eighth photoelectric conversion elements (PD1˜PD8) in FIG. 2 and their respective first to eighth transfer transistors (TX1˜TX8) in which, the first transfer transistor TX1 is located adjacent to and is electrically coupled to the first photoelectric conversion element PD1 to transfer the photocharge accumulated in the first photoelectric conversion element PD1 out for readout, the second transfer transistor TX2 is located adjacent to and is electrically coupled to the second photoelectric conversion element PD2 to transfer the photocharge accumulated in the second photoelectric conversion element PD2 out for readout, and so on and so forth for other photoelectric conversion elements PD3 through PD8. The circuit in FIG. 3 shows that the first to fourth pixel groups (PG1˜PG4) formed by first to eighth photoelectric conversion elements (PD1˜PD8) as shown in FIG. 2 are designed to share a common shared circuit that includes, a floating diffusion region FD that is located adjacent to the first to fourth pixel groups (PG1˜PG4) to receive photocharge therefrom, a reset transistor RX located adjacent to and electrically coupled to the floating diffusion region FD, a drive transistor DX located adjacent to and electrically coupled to the floating diffusion region FD, a selection transistor SX located adjacent to and electrically coupled to the drive transistor DX, a dual conversion gain (DCG) transistor CX located adjacent to and electrically coupled to the floating diffusion region FD, and a DCG capacitor (Cg). In this particular example in FIG. 3, the shared pixel structure 300 may have a 4-transistor (4TR) pixel structure.

Each of the first to eighth photoelectric conversion elements (PD1˜PD8) may generate and accumulate photocharges corresponding to the intensity of incident light. The first to eighth photoelectric conversion elements (PD1˜PD8) may be included in eight phase difference detection pixels included in the shared pixel structure 300, respectively.

For example, when the shared pixel structure 300 corresponds to the first to fourth pixel groups (PG1˜PG4), the first photoelectric conversion element PD1 may be included in the first phase difference detection pixel (LPX) of the first pixel group PG1, and the second photoelectric conversion element PD2 may be included in the second phase difference detection pixel (RPX) of the first pixel group PG1. In addition, the third photoelectric conversion element PD3 may be included in the first phase difference detection pixel (LPX) of the second pixel group PG2, and the fourth photoelectric conversion element PD4 may be included in the second phase difference detection pixel (RPX) of the second pixel group PG2. In addition, the fifth photoelectric conversion element PD5 may be included in the first phase difference detection pixel (LPX) of the third pixel group PG3, and the sixth photoelectric conversion element PD6 may be included in the second phase difference detection pixel (RPX) of the third pixel group PG3. Finally, the seventh photoelectric conversion element PD7 may be included in the first phase difference detection pixel (LPX) of the fourth pixel group PG4, and the eighth photoelectric conversion element PD8 may be included in the second phase difference detection pixel (RPX) of the fourth pixel group PG4.

In the above description, the shared pixel structure 300 corresponds to the first to fourth pixel groups (PG1˜PG4). As mentioned above, the shared pixel structure 300 can be applied to other pixel groups, e.g., the fifth to eighth pixel groups (PG5˜PG8), the ninth to twelfth pixel groups (PG9˜PG12), and/or the thirteenth to sixteenth pixel groups (PG13˜PG16). For example, when the shared pixel structure 300 corresponds to the thirteenth to sixteenth pixel groups (PG13˜PG16), the photoelectric conversion elements may be respectively included in the phase difference detection pixels of the thirteenth to sixteenth pixel group (PG13˜PG16) in substantially the same manner as described for the first to fourth pixel groups (PG1˜PG4).

Each of the first to eighth photoelectric conversion elements (PD1˜PD8) may be implemented as a photodiode, a phototransistor, a photogate, a pinned photodiode, or a combination thereof. If each of the first to eighth photoelectric conversion elements (PD1˜PD8) is implemented as a photodiode, each photoelectric conversion element (PD1˜PD8) may be or include a region that is doped with impurities of a second conductive type (e.g., N-type impurities) in a substrate including impurities of a first conductive type (e.g., P-type impurities).

The first to eighth transfer transistors (TX1˜TX8) may be respectively coupled between the corresponding photoelectric conversion element from among the first to eighth photoelectric conversion elements (PD1˜PD8) and the floating diffusion region FD. In more detail, the first transfer transistor TX1 may be connected between the first photoelectric conversion element PD1 and the floating diffusion region FD, the second transfer transistor TX2 may be connected between the second photoelectric conversion element PD2 and the floating diffusion region FD, the third transfer transistor TX3 may be connected between the third photoelectric conversion element PD3 and the floating diffusion region FD, the fourth transfer transistor TX4 may be connected between the fourth photoelectric conversion element PD4 and the floating diffusion region FD, the fifth transfer transistor TX5 may be connected between the fifth photoelectric conversion element PD5 and the floating diffusion region FD, the sixth transfer transistor TX6 may be connected between the sixth photoelectric conversion element PD6 and the floating diffusion region FD, the seventh transfer transistor TX7 may be connected between the seventh photoelectric conversion element PD7 and the floating diffusion region FD, and the eighth transfer transistor TX8 may be connected between the eighth photoelectric conversion element PD8 and the floating diffusion region FD. The first to eighth transfer transistors (TX1˜TX8) may be turned on or off in response to first to eighth transfer signals (TS1˜TS8), respectively. When the first to eight transfer transistors (TX1˜TX8) are turned on, the first to eighth transfer transistors (TX1˜TX8) may transfer photocharges accumulated in the first to eighth photoelectric conversion elements (PD1˜PD8) to the floating diffusion region FD. In more detail, the first transfer transistor TX1 may transfer photocharges accumulated in the first photoelectric conversion element PD1 to the floating diffusion region FD in response to being turned on, the second transfer transistor TX2 may transfer photocharges accumulated in the second photoelectric conversion element PD2 to the floating diffusion region FD in response to being turned on, the third transfer transistor TX3 may transfer photocharges accumulated in the third photoelectric conversion element PD3 to the floating diffusion region FD in response to being turned on, the fourth transfer transistor TX4 may transfer photocharges accumulated in the fourth photoelectric conversion element PD4 to the floating diffusion region FD in response to being turned on, the fifth transfer transistor TX5 may transfer photocharges accumulated in the fifth photoelectric conversion element PD5 to the floating diffusion region FD in response to being turned on, the sixth transfer transistor TX6 may transfer photocharges accumulated in the sixth photoelectric conversion element PD6 to the floating diffusion region FD in response to being turned on, the seventh transfer transistor TX7 may transfer photocharges accumulated in the seventh photoelectric conversion element PD7 to the floating diffusion region FD in response to being turned on, and the eighth transfer transistor TX8 may transfer photocharges accumulated in the eighth photoelectric conversion element PD8 to the floating diffusion region FD in response to being turned on. In some implementations, a time interval in which the first transfer transistor TX1 is turned on, a time interval in which the second transfer transistor TX2 is turned on, a time interval in which the third transfer transistor TX3 is turned on, a time interval in which the fourth transfer transistor TX4 is turned on, a time interval in which the fifth transfer transistor TX5 is turned on, a time interval in which the sixth transfer transistor TX6 is turned on, a time interval in which the seventh transfer transistor TX7 is turned on, and a time interval in which the eighth transfer transistor TX8 is turned on may be separated from one another.

The reset transistor RX may be connected between the floating diffusion region FD and a power-supply voltage (VDD), and a voltage of the floating diffusion region FD may be reset to the power-supply voltage (VDD) in response to a pixel reset signal RS.

The floating diffusion region FD may accumulate photocharges received from the first to eighth transfer transistors (TX1˜TX8). For example, the floating diffusion region FD may be or include a region that is doped with impurities of a second conductive type (e.g., N-type impurities) in a substrate (e.g., a P-type substrate) including impurities of a first conductive type (e.g., P-type impurities). In this case, the substrate and the impurity doped region may be modeled as a junction capacitor.

The drive transistor DX may be coupled between the selection transistor SX and the power-supply voltage (VDD), may amplify a change in electrical potential of the floating diffusion region FD that has received photocharges accumulated in the first to eighth photoelectric conversion elements (PD1˜PD8), and may transmit the amplified result to the selection transistor SX.

The selection transistor SX may be coupled between the drive transistor DX and the output signal line (or column line), and may be turned on by a row selection signal (SEL), so that the selection transistor SX may output the electrical signal received from the drive transistor DX as a pixel signal (VOUT).

A DCG transistor (CX) may receive a gain control signal (CS) through a gate thereof, and one terminal (e.g., drain) of the DCG transistor (CX) may be connected to the floating diffusion region FD and the other terminal (e.g., source) of the DCG transistor (CX) may be connected to a DCG capacitor (Cg). The DCG transistor (CX) may be turned on or off in response to a gain control signal (CS). The turned-on DCG transistor (CX) may additionally provide capacitance corresponding to the sum of parasitic capacitance of the DCG transistor (CX) and capacitance of the DCG capacitor (Cg) to the floating diffusion region FD. On the other hand, the turned-off DCG transistor (CX) may not additionally provide capacitance corresponding to the sum of parasitic capacitance of the DCG transistor (CX) and capacitance of the DCG capacitor (Cg) to the floating diffusion region FD. That is, capacitance of the floating diffusion region FD when the DCG transistor (CX) is turned on may be greater than capacitance of the floating diffusion region FD when the DCG transistor (CX) is turned off. The capacitance of the floating diffusion region FD may determine a conversion gain, which is a ratio between photocharge accumulated in the floating diffusion region FD and an electrical signal (voltage) output by the drive transistor DX. That is, a floating diffusion region FD with a relatively large capacitance may provide a relatively low conversion gain, and a floating diffusion region FD with a relatively small capacitance may provide a relatively high conversion gain. By varying the capacitance of the floating diffusion region FD to perform readout of photocharges, a dynamic range capable of obtaining a valid pixel signal may be expanded.

Each of the transfer signal (TS), the pixel reset signal (RS), the row selection signal (SEL), and the gain control signal (CS) may be provided from the row driver 120.

The DCG capacitor (Cg) may refer to a capacitor with a predetermined capacitance, and one terminal of the DCG capacitor (Cg) may be connected to the DCG transistor (CX) and the other terminal of the DCG capacitor (Cg) may be connected to a ground voltage. For example, the DCG capacitor (Cg) may include at least one of a Metal-Insulator-Metal (MIM) capacitor, a Metal-Insulator-Polysilicon (MIP) capacitor, a Metal-Oxide-Semiconductor (MOS) capacitor, and a junction capacitor.

According to the shared pixel structure 300 shown in FIG. 3, not only capacitance corresponding to the parasitic capacitance of the DCG transistor (CX), but also capacitance corresponding to the capacitance of the DCG capacitor (Cg) may be additionally stored in the floating diffusion region FD. By adjusting the capacitance of the DCG capacitor (Cg), a relatively large capacitance may be provided to the floating diffusion region FD.

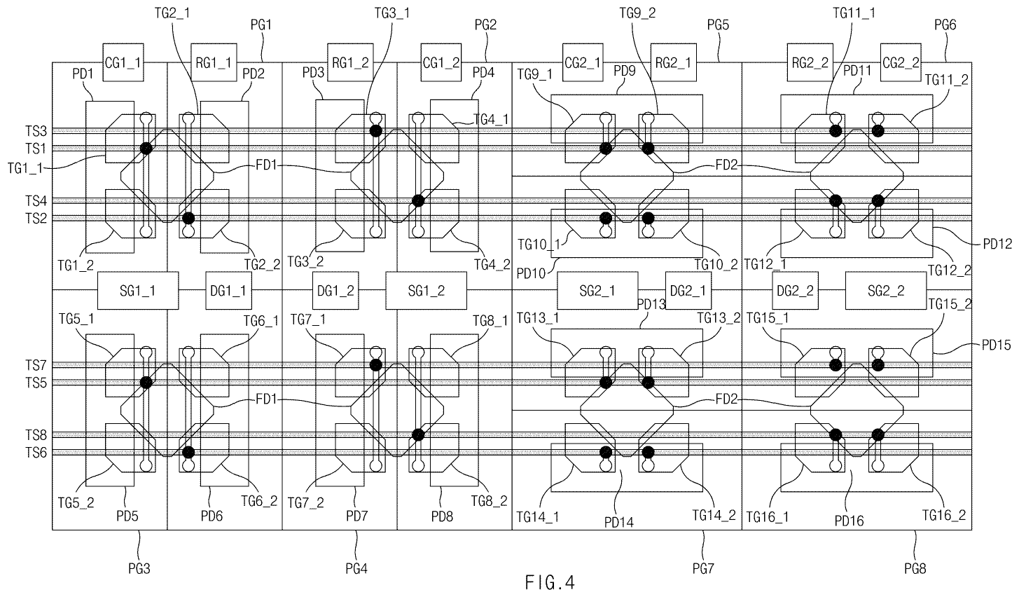

FIG. 4 is a diagram illustrating an example of a layout structure of elements included in the shared pixel structure shown in FIG. 3 based on some implementations of the disclosed technology.

Referring to FIGS. 2 to 4, an example of the layout structure for the first to fourth pixel groups (PG1˜PG4) and the fifth to eighth pixel groups (PG5˜PG8) is shown. The first to fourth pixel groups (PG1˜PG4) may correspond to the shared pixel structure 300, and the fifth to eighth pixel groups (PG5˜PG8) may correspond to the shared pixel structure 300.

Each of the first to fourth pixel groups (PG1˜PG4) may include first to eighth photoelectric conversion elements (PD1˜PD8). The first to eighth photoelectric conversion elements (PD1˜PD8) may be symmetrically arranged with respect to the center of the first to fourth pixel groups (PG1˜PG4). In more detail, the first and second photoelectric conversion elements (PD1˜PD2) may be symmetrically arranged on left and right sides of the center of the first pixel group PG1, the third and fourth photoelectric conversion elements (PD3˜PD4) may be symmetrically arranged on left and right sides of the center of the second pixel group PG2, the fifth and sixth photoelectric conversion elements (PD5˜PD6) may be symmetrically arranged on left and right sides of the center of the third pixel group PG3, and the seventh and eighth photoelectric conversion elements (PD7˜PD8) may be symmetrically arranged on left and right sides of the center of the fourth pixel group PG4. In this case, each of the photoelectric conversion elements (PD1˜PD8) may be formed in a shape extending in the vertical direction (or the first direction) such that the length of a horizontal side of each photoelectric conversion element is shorter than the length of a vertical side of each photoelectric conversion element.

A floating diffusion region FD1 may be disposed at the center of each of the first to fourth pixel groups (PG1˜PG4). The floating diffusion regions (FD1) respectively disposed in the first to fourth pixel groups (PG1˜PG4) may be electrically connected to each other, resulting in formation of a single node. Although it is assumed that the center of each pixel group and the center of the floating diffusion region coincide with each other for convenience of explanation, other implementations are also possible, and it should be noted that the center of each pixel group and the center of the floating diffusion region may be spaced apart from each other by a predetermined distance within each pixel group.

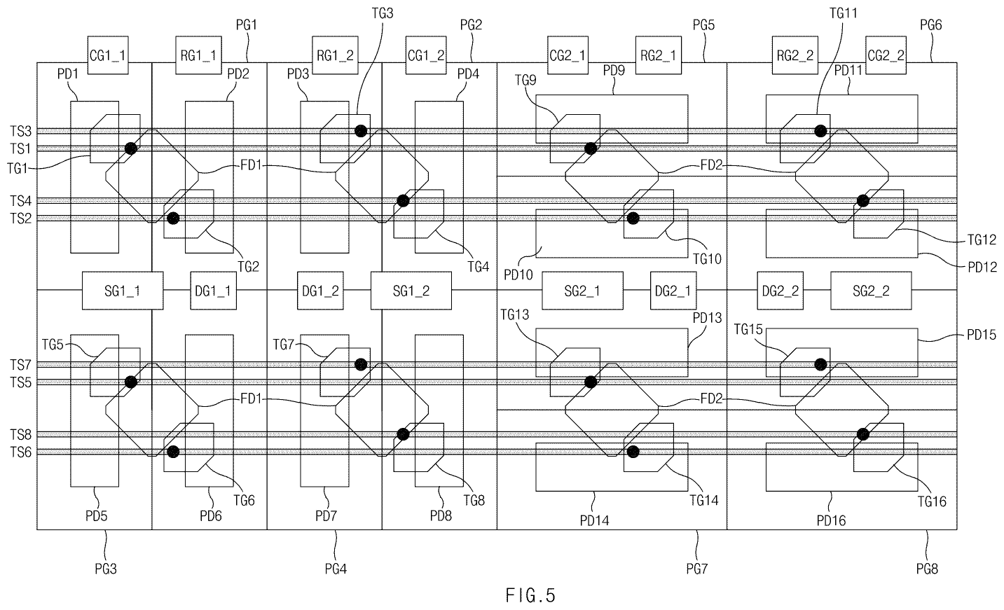

One side of each of the first transfer gates (TG1_1, TG1_2) of the first transfer transistor TX1 may overlap the first photoelectric conversion element PD1, and another side of each of the first transfer gates (TG1_1, TG1_2) of the first transfer transistor TX1 may overlap the floating diffusion region FD1. The first transfer gates (TG1_1, TG1_2) may be vertically spaced apart from each other by a predetermined distance in the extension direction of the first photoelectric conversion element PD1. However, the first transfer gates (TG1_1, TG1_2) may be electrically interconnected to operate as a single transfer gate. The first transfer gate (TG1_2) may be referred to as a first additional transfer gate and the first additional transfer gate (TG1_2) can be omitted as shown in FIG. 5.

One side of each of the second transfer gates (TG2_1, TG2_2) of the second transfer transistor TX2 may overlap the second photoelectric conversion element PD2, and another side of each of the second transfer gates (TG2_1, TG2_2) of the second transfer transistor TX2 may overlap the floating diffusion region FD1. The second transfer gates (TG2_1, TG2_2) may be vertically spaced apart from each other by a predetermined distance in the extension direction of the second photoelectric conversion element PD2. However, the second transfer gates (TG2_1, TG2_2) may be electrically connected to each other to operate as a single transfer gate. The second transfer gate (TG2_1) may be referred to as a second additional transfer gate and the second additional transfer gate (TG2_1) can be omitted as shown in FIG. 5.

The first transfer gates (TG1_1, TG1_2) and the second transfer gates (TG2_1, TG2_2) may be symmetrically arranged with respect to a vertical line (i.e., a boundary between the first phase difference detection pixel LPX and the second phase difference detection pixel RPX) passing through the center of the first pixel group PG1. In addition, the first and second transfer gates (TG1_1, TG2_1) and the first and second transfer gates (TG1_2, TG2_2) may be symmetrically arranged with respect to a horizontal line passing through the center of the first pixel group PG1.

The transfer gates (e.g., TG3_1, TG3_2, TG4_1, TG4_2) of the third to eighth transfer transistors (TX3˜TX8) included in the second to fourth pixel groups (PG2˜PG4) may be disposed in substantially the same manner as the transfer gates (TG1_1, TG1_2, TG2_1, TG2_2) of the first transfer transistor TX1 and the second transfer transistor TX2 included in the first pixel group PG1, and a more detailed description thereof will herein be omitted to avoid duplication.

A DCG gate (CG1_1) of the DCG transistor CX and a reset gate (RG1_1) of the reset transistor RX may be disposed at an upper boundary of the first pixel group PG1, and a DCG gate (CG1_2) of the DCG transistor CX and a reset gate (RG1_2) of the reset transistor RX may be disposed at an upper boundary of the second pixel group PG2. In some implementations, the upper boundary may mean a boundary between a specific region and a region disposed over the specific region. The DCG gate (CG1_1) and the reset gate (RG1_1) may be arranged symmetrical to the DCG gate (CG1_2) and the reset gate (RG1_2) with respect to a boundary between the first pixel group PG1 and the second pixel group PG2. In the implementation, the DCG gate (CG1_1) and the DCG gate (CG1_2) may be electrically connected to each other to operate as a single DCG gate. The reset gate (RG1_1) and the reset gate (RG1_2) may be electrically connected to each other to operate as a single reset gate.

A selection gate (SG1_1) of the selection transistor SX and a drive gate (DG1_1) of the drive transistor DX may be disposed at an upper boundary of the third pixel group PG3, and a selection gate (SG1_1) of the selection transistor SX and a drive gate (DG1_2) of the drive transistor DX may be disposed at an upper boundary of the fourth pixel group PG4. The selection gate (SG1_1) and the drive gate (DG1_1) may be arranged symmetrical to the selection gate (SG1_2) and the drive gate (DG1_2) with respect to a boundary between the third pixel group PG3 and the fourth pixel group PG4. On the other hand, the selection gate (SG1_1) and the selection gate (SG1_2) may be electrically connected to each other to operate as a single selection gate. The drive gate (DG1_1) and the drive gate (DG1_2) may be electrically connected to each other to operate as a single drive gate. The region of each of the drive gates (DG1_1, DG1_2) may be larger than the region of each of the selection gates (SG1_1, SG1_2). This serves to improve noise characteristics of the drive transistor (DX) by increasing the region of the drive gates (DG1_1, DG1_2) as much as possible.

In the implementations, the fifth to eighth pixel groups (PG5˜PG8) may include the ninth to sixteenth photoelectric conversion elements (PD9˜PD16). In more detail, the fifth pixel group PG5 may include the ninth and tenth photoelectric conversion elements (PD9˜PD10), the sixth pixel group PG6 may include the eleventh and twelfth photoelectric conversion elements (PD11˜PD12), the seventh pixel group PG7 may include the thirteenth and fourteenth photoelectric conversion elements (PD13˜PD14), and the eighth pixel group PG8 may include the fifteenth and sixteenth photoelectric conversion elements (PD15˜PD16). The ninth to sixteenth photoelectric conversion elements (PD9˜PD16) may be arranged symmetrical to each other with respect to the centers of the fifth to eighth pixel groups (PG5˜PG8). In more detail, the ninth to tenth photoelectric conversion elements (PD9˜PD10) may be symmetrically arranged on upper and lower sides of the center of the fifth pixel group PG5, the eleventh to twelfth photoelectric conversion elements (PD11˜PD12) may be symmetrically arranged on upper and lower sides of the center of the sixth pixel group PG6, the thirteenth to fourteenth photoelectric conversion elements (PD13˜PD14) may be symmetrically arranged on upper and lower sides of the center of the seventh pixel group PG7, and the fifteenth to sixteenth photoelectric conversion elements (PD15˜PD16) may be symmetrically arranged on upper and lower sides of the center of the eighth pixel group PG8. The photoelectric conversion elements in each of the fifth to eighth pixel group (PG5˜PG8) are vertically symmetric to each other with respect to the center of the corresponding pixel group. In this case, each of the photoelectric conversion element (PD9˜PD16) may be formed in a shape extending in the horizontal direction (or the second direction) such that the length of a horizontal side of each photoelectric conversion element is longer than the length of a vertical side of each photoelectric conversion element. The first direction in which each of the first to eighth photoelectric conversion elements (PD1˜PD8) extends and the second direction in which each of the ninth to sixteenth photoelectric conversion elements (PD9˜PD16) extends may be perpendicular to each other. In addition, the region (or volume) of each of the first to eighth photoelectric conversion elements (PD1˜PD8) may be substantially the same as the region (or volume) of each of the ninth to sixteenth photoelectric conversion elements (PD9˜PD16). For example, the first to sixteenth photoelectric conversion elements (PD1˜PD16) can have a same size. In some other implementations, the region (or volume) of at least some of the first to sixteenth photoelectric conversion elements (PD1˜PD16) may be different from the region (or volume) of the remaining photoelectric conversion elements.

A floating diffusion region FD2 may be disposed at the center of each of the fifth to eighth pixel groups (PG5˜PG8), and the floating diffusion regions FD2 disposed in the fifth to eighth pixel groups (PG5˜PG8) may be electrically connected to each other to form a single node.

One side of each of the ninth transfer gates (TG9_1, TG9_2) of the ninth transfer transistor TX9 may overlap the ninth photoelectric conversion element PD9, and another side of each of the ninth transfer gates (TG9_1, TG9_2) of the ninth transfer transistor TX9 may overlap the floating diffusion region FD2. The ninth transfer gates (TG9_1, TG9_2) may be horizontally spaced apart from each other by a predetermined distance in the extension direction of the ninth photoelectric conversion element PD9. However, the ninth transfer gates (TG9_1, TG9_2) may be electrically connected to each other to operate as a single transfer gate. The ninth transfer gate (TG9_2) may be referred to as a ninth additional transfer gate and the ninth additional transfer gate (TG9_2) can be omitted as shown in FIG. 5.

One side of each of the tenth transfer gates (TG10_1, TG10_2) of the tenth transfer transistor TX10 may overlap the tenth photoelectric conversion element PD10, and the other side of each of the tenth transfer gates (TG10_1, TG10_2) of the tenth transfer transistor TX10 may overlap the floating diffusion region FD2. The tenth transfer gates (TG10_1, TG10_2) may be horizontally spaced apart from each other by a predetermined distance in the extension direction of the tenth photoelectric conversion element PD10. However, the tenth transfer gates (TG10_1, TG10_2) may be electrically connected to each other to operate as a single transfer gate. The tenth transfer gate (TG10_1) may be referred to as a tenth additional transfer gate and the tenth additional transfer gate (TG10_1) can be omitted as shown in FIG. 5.

The ninth transfer gates (TG9_1, TG9_2) and the tenth transfer gates (TG10_1, TG10_2) may be arranged symmetrically with respect to a horizontal line passing through the center of the fifth pixel group PG5. In addition, the ninth and tenth transfer gates (TG9_1, TG10_1) and the ninth and tenth transfer gates (TG9_2, TG10_2) may be arranged symmetrically with respect to a vertical line passing through the center of each of the fifth pixel group PG5.

The transfer gates (e.g., TG11_1, TG11_2, TG12_1, TG12_2) of the eleventh to sixteenth transfer transistors (TX11˜TX16) included in the sixth to eighth pixel groups (PG6˜PG8) may be arranged in substantially the same manner as the transfer gates (TG9_1, TG9_2, TG10_1, TG10_2) of the ninth transfer transistor TX9 and the tenth transfer transistor TX10 included in the fifth pixel group PG5, and a more detailed description thereof will herein be omitted to avoid duplication.

The DCG gate (CG2_1) and the reset gate (RG2_1) disposed at an upper boundary of the fifth pixel group PG5 and the DCG gate (CG2_2) and the reset gate (RG2_2) disposed at an upper boundary of the sixth pixel group PG6 may be disposed in substantially the same manner as the above DCG gates (CG1_1, CG1_2) and the above reset gates (RG1_1, RG1_2).

In addition, the selection gate (SG2_1) and the drive gate (DG2_1) disposed at an upper boundary of the seventh pixel group PG7 and the selection gate (SG2_2) and the drive gate (DG2_2) disposed at an upper boundary of the eighth pixel group PG8 may be disposed in substantially the same manner as the above selection gates (SG1_1, SG1_2) and the above drive gates (DG1_1, DG1_2).

A signal for supplying the first transfer signal TS1 to the first transfer gates (TG1_1, TG1_2) and the ninth transfer gates (TG9_1, TG9_2), which correspond to the transfer gates of the first transfer transistor TX1 shown in FIG. 3, may extend in the horizontal direction (or the row direction). A signal line for supplying the first transfer signal TS1 may be connected to a signal line that commonly transmits the first transfer signal TS1 to the first transfer gates (TG1_1, TG1_2), as represented by black dots of FIG. 4. In addition, the signal line for supplying the first transfer signal TS1 may be connected to the signal line for transmitting the first transfer signal TS1 to each of the ninth transfer gates (TG9_1, TG9_2), as represented by black dots of FIG. 4. Here, a signal line for supplying the first transfer signal TS1 and a signal line for transmitting the first transfer signal TS1 to each transfer gate may be arranged in different interconnect layers from each other.

Likewise, each of signal lines for supplying the second to eighth transfer signals (TS2˜TS8) to the transfer gates, which correspond to the transfer gates of the second to eighth transfer transistors (TX2˜TX8) shown in FIG. 3, may extend in the horizontal direction (or in the row direction). In addition, signal lines for supplying the corresponding transfer signals to transfer gates corresponding to the second to eighth transfer signals (TS2˜TS8) may be connected to the signal lines for supplying the second to eighth transfer signals (TS2˜TS8) in substantially the same manner as described above.

In addition, the signal lines for supplying the first to eighth transfer signals (TS1˜TS8) may overlap transfer gates corresponding to the first to eighth transfer signals (TS1˜TS8), respectively.

According to the layout structure as shown in FIG. 4, two transfer gates may be arranged for each photoelectric conversion element, and transfer gates included in the pixel group corresponding to one microlens may be arranged symmetrically in the horizontal and vertical directions with respect to the center of the pixel group, and transfer gates included in each pixel group may be arranged at the same position with respect to the center of each pixel group regardless of the type of each pixel group, resulting in symmetry between pixel groups to affect signal characteristics.

In addition, since two transfer gates are disposed for each photoelectric conversion element, photocharge transfer efficiency from the photoelectric conversion element to the floating diffusion region can be improved.

FIG. 5 is a diagram illustrating another example of the layout structure of elements included in the shared pixel structure shown in FIG. 3 based on some implementations of the disclosed technology.

Referring to FIGS. 2 to 5, other examples of the layout structure for the first to fourth pixel groups (PG1˜PG4) and the fifth to eighth pixel groups (PG5˜PG8) are shown. The first to fourth pixel groups (PG1˜PG4) may correspond to the shared pixel structure 300, and the fifth to eighth pixel groups (PG5˜PG8) may correspond to the shared pixel structure 300.

The layout structure shown in FIG. 5 may be substantially the same as the layout structure described in FIG. 4 except for some differences. In the below, the layout structure of FIG. 5 will be described centering upon such differences distinguished from those of FIG. 4.

One transfer gate (TG1˜TG16) may be disposed for each of the first to sixteenth photoelectric conversion elements (PD1˜PD16). For example, one transfer gate TG1 may be disposed in the first photoelectric conversion element PD1, one transfer gate TG2 may be disposed in the second photoelectric conversion element PD2, and one transfer gate TG3 may be disposed in the third photoelectric conversion element PD3. In this way, the fourth to sixteenth transfer gates TG4, TG5, TG6, TG7, TG8, TG9, TG10, TG11, TG12, TG13, TG14, TG15, and TG16 may be disposed in the fourth to sixteenth photoelectric conversion elements PD4, PD5, PD6, PD7, PD8, PD9, PD10, PD11, PD12, PD13, PD14, PD15, and PD16, respectively.

More specifically, the transfer gates (TG1, TG3, TG5, TG7) may be respectively disposed at top-left sides of the photoelectric conversion elements (PD1, PD3, PD5, PD7) of the first phase difference detection pixels (LPXs) of the first to fourth pixel groups (PG1˜PG4) with respect to the center of the first to fourth pixel groups (PG1˜PG4).

The transfer gates (TG2, TG4, TG6, TG8) may be respectively disposed at bottom-right sides of the photoelectric conversion elements (PD2, PD4, PD6, PD8) of the second phase difference detection pixels (RPXs) of the first to fourth pixel groups (PG1˜PG4) with respect to the center of the first to fourth pixel groups (PG1˜PG4).

The transfer gates (TG9, TG11, TG13, TG15) may be respectively disposed at top-left sides of the photoelectric conversion elements (PD9, PD11, PD13, PD15) of the third phase difference detection pixels (TPXs) of the fifth to eighth pixel groups (PG5˜PG8) with respect to the center of the fifth to eighth pixel groups (PG5˜PG8).

The transfer gates (TG10, TG12, TG14, TG16) may be respectively disposed at bottom-right sides of the photoelectric conversion elements (PD10, PD12, PD14, PD16) of the fourth phase difference detection pixels (BPXs) of the fifth to eighth pixel groups (PG5˜PG8) with respect to the center of the fifth to eighth pixel groups (PG5˜PG8).

According to the layout structure as shown in FIG. 5, only one transfer gate may be arranged for each photoelectric conversion element, and transfer gates included in the pixel group corresponding to one microlens may be arranged symmetrically in the diagonal direction with respect to the center of the pixel group, and transfer gates having the same position and size can be used regardless of the types of phase difference detection pixels included in the pixel group, thereby ensuring symmetry between pixel groups to affect signal characteristics.

Although the embodiment of FIG. 5 has disclosed that the transfer gates included in each pixel group are arranged at the top-left and bottom-right sides with respect to the center of the pixel group, the scope of the disclosed technology is not limited thereto, and it should be noted that the transfer gates may also be disposed at the bottom-left and top-right sides with respect to the center of the pixel group.

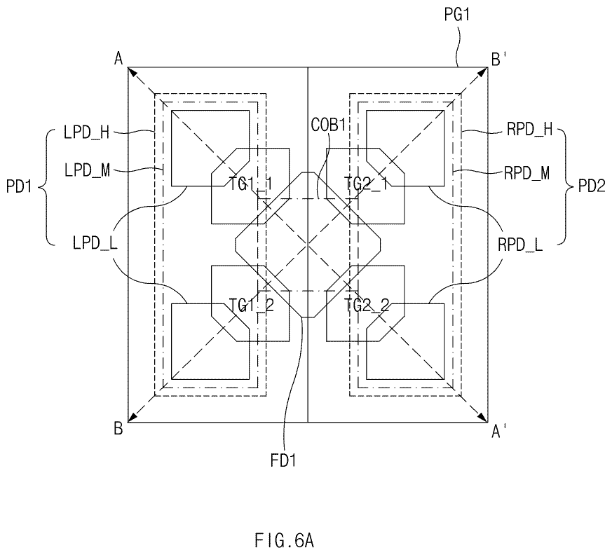

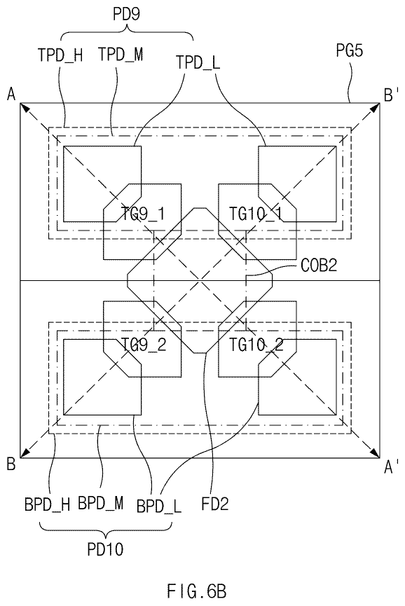

FIG. 6A is a detailed diagram illustrating an example of the layout structure for the first pixel group PG1 shown in FIG. 4 based on some implementations of the disclosed technology.

Referring to FIG. 6A, the first pixel group PG1 shown in FIG. 4 is illustrated in more detail. FIG. 6A is a diagram for explaining characteristics of the photoelectric conversion elements (PD1, PD2) included in the first pixel group PG1, and the following description will be given centering upon such characteristics of the photoelectric conversion elements (PD1, PD2) included in the first pixel group PG1.

The first photoelectric conversion element PD1 may include impurity layers (LPD_H, LPD_M, LPD_L) formed at different depths using different ion implantation energies. In the example, three different impurity layers (LPD_H, LPD_M, LPD_L) may be formed at three different depths using three different ion implantation energies. The impurity layer (LPD_H) may be a layer formed by implanting impurities of the second conductivity type (e.g., N-type) to the greatest depth (as compared to the depths at which the impurity layers LPD_M and LPD_L are formed) using the highest ion implantation energy (as compared to the ion implantation energies for forming the impurity layers LPD_M and LPD_L), and the impurity layer (LPD_L) may be a layer formed by implanting impurities of the second conductivity type (e.g., N-type) to the smallest depth (as compared to the depths at which the impurity layers LPD_H and LPD_M are formed) using the lowest ion implantation energy (as compared to the ion implantation energies for forming the impurity layers LPD_H and LPD_M). Additionally, the impurity layer (LPD_M) may be a layer formed by implanting impurities of the second conductivity type (e.g., N-type) to a medium depth (as compared to the depths at which the impurity layers LPD_H and LPD_L are formed) using intermediate ion implantation energy (as compared to the ion implantation energies for forming impurity layers LPD_H and LPD_L).

The second photoelectric conversion element PD2 may include impurity layers (RPD_H, RPD_M, RPD_L) formed at different depths using different ion implantation energies. In the example, the impurity layer (RPD_H) may be a layer formed by implanting impurities of the second conductivity type (e.g., N-type) to the greatest depth (as compared to the depths at which the impurity layers RPD_M and RPD_L are formed) using the highest ion implantation energy (as compared to the ion implantation energies for forming the impurity layers RPD_M and RPD_L), and the impurity layer (RPD_L) may be a layer formed by implanting impurities of the second conductivity type (e.g., N-type) to the smallest depth (as compared to the depths at which the impurity layers RPD_H and RPD_M are formed) using the lowest ion implantation energy (as compared to the ion implantation energies for forming the impurity layers RPD_H and RPD_M). Additionally, the impurity layer (RPD_M) may be a layer formed by implanting impurities of the second conductivity type (e.g., N-type) to a medium depth (as compared to the depths at which the impurity layers RPD_H and RPD_L are formed) using intermediate ion implantation energy (as compared to the ion implantation energies for forming impurity layers RPD_H and RPD_L).

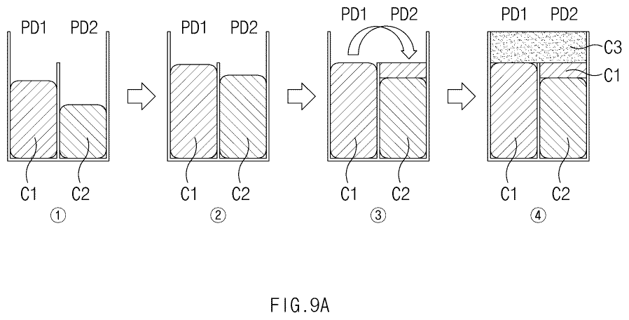

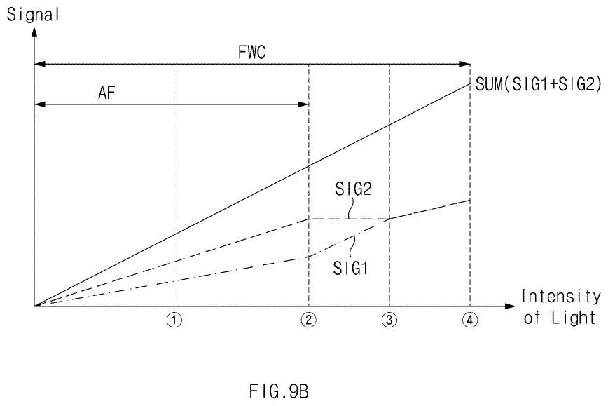

In the example, the impurity layer (LPD_M) of the first photoelectric conversion element PD1 and the impurity layer (RPD_M) of the second photoelectric conversion element PD2 may be formed simultaneously through the same process. In addition, through the above-described process, a charge overflow barrier (COB1) connecting the two impurity layers (LPD_M, RPD_M) to each other can be formed. The charge overflow barrier (COB1) may operate as a potential barrier between the first photoelectric conversion element PD1 and the second photoelectric conversion element PD2. Specifically, when the potential of at least one of the first photoelectric conversion element PD1 and the second photoelectric conversion element PD2 is less than or equal to a predetermined potential, the charge overflow barrier (COB1) may block movement of photocharges between the first photoelectric conversion element PD1 and the second photoelectric conversion element PD2. Conversely, when the potential of at least one of the first photoelectric conversion element PD1 and the second photoelectric conversion element PD2 exceeds a predetermined potential, the charge overflow barrier CO1 may allow movement of photocharges between the first photoelectric conversion element PD1 and the second photoelectric conversion element PD2. The above-described operation ensures linearity of the pixel signal, and a more detailed description thereof will be given later with reference to FIGS. 9A and 9B.

In addition, the charge overflow barrier (COB1) may be arranged to overlap the floating diffusion region FD1. Since the charge overflow barrier (COB1) is formed at a medium depth and can be spaced apart from one surface (e.g., front surface) of the substrate by a predetermined distance, the charge overflow barrier (COB1) may be minimally affected by other elements (e.g., gates of transistors) and a design margin on the layout may be provided to reduce the size of a gap or spacing between such elements, such that each pixel can be miniaturized.

In addition, the impurity layers (LPD_L, RPD_L) each having the smallest depth may have a smaller region than either the regions of the impurity layers (LPD_M, RPD_M) each having a medium depth or the regions of the impurity layers (LPD_H, RPD_H) each having the greatest depth. This serves to prevent the first photoelectric conversion element PD1 and the second photoelectric conversion element PD2 from contacting the floating diffusion region FD1.

FIG. 6B is a detailed diagram illustrating an example of the layout structure for the fifth pixel group PG5 shown in FIG. 4 based on some implementations of the disclosed technology.

Referring to FIGS. 6A and 6B, the fifth pixel group PG5 of FIG. 4 is illustrated in more detail. FIG. 6B is a diagram for explaining characteristics of the photoelectric conversion elements (PD9, PD10) included in the fifth pixel group PG5, and the following description will be given centering upon such characteristics of the photoelectric conversion elements (PD9, PD10) included in the fifth pixel group PG5.

The ninth photoelectric conversion element PD9 may include impurity layers (TPD_H, TPD_M, TPD_L) formed at different depths using different ion implantation energies.

The tenth photoelectric conversion element PD10 may include impurity layers (BPD_H, BPD_M, BPD_L) formed at different depths using different ion implantation energies.

In addition, the impurity layers (TPD_M, BPD_M), each of which is formed at a medium depth, may be connected to each other through a charge overflow barrier (COB2).

Whereas the ninth photoelectric conversion element PD9 and the tenth photoelectric conversion element PD10 shown in FIG. 6B are different from the first photoelectric conversion element PD1 and the second photoelectric conversion element PD2 shown in FIG. 6A in terms of their extension directions, the ninth photoelectric conversion element PD9 and the tenth photoelectric conversion element PD10 are substantially the same as the first photoelectric conversion element PD1 and the second photoelectric conversion element PD2 in terms of a fabrication process, a structure, and materials, and as such redundant description thereof will herein be omitted for brevity.

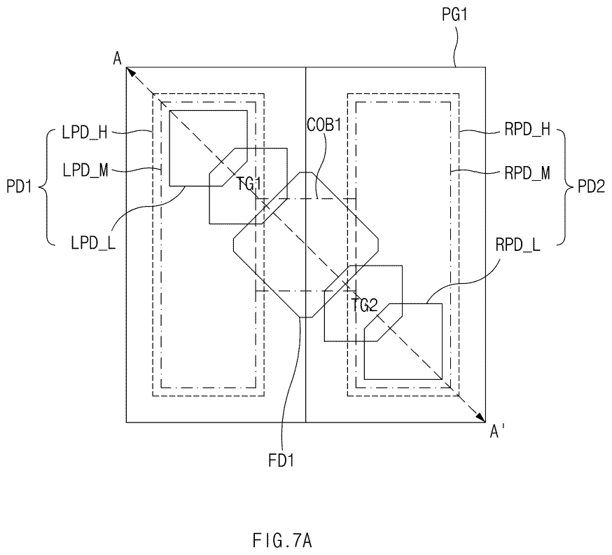

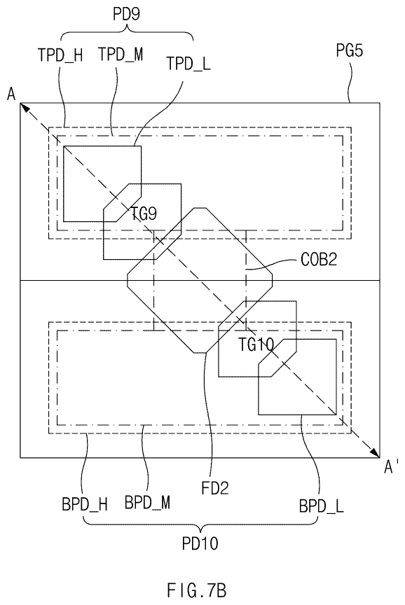

FIG. 7A is a detailed diagram illustrating another example of the layout structure for the first pixel group PG1 shown in FIG. 5 based on some implementations of the disclosed technology.

Referring to FIGS. 5, 6A, and 7A, the first pixel group PG1 shown in FIG. 5 is illustrated in more detail. As described above, one transfer gate TG1 may be arranged to correspond to the photoelectric conversion element PD1, and the other transfer gate TG2 may be arranged to correspond to the photoelectric conversion element PD2.

FIG. 7A is a diagram for explaining characteristics of the photoelectric conversion elements (PD1, PD2) included in the first pixel group PG1, but the photoelectric conversion elements (PD1, PD2) shown in FIG. 7A are substantially the same as the photoelectric conversion elements (PD1, PD2) shown in FIG. 6A in terms of a fabrication process, a structure, and materials, and as such redundant description thereof will herein be omitted for brevity.

FIG. 7B is a detailed diagram illustrating another example of the layout structure for the fifth pixel group PG5 shown in FIG. 5 based on some implementations of the disclosed technology.

Referring to FIGS. 5, 6B, and 7B, the fifth pixel group PG5 shown in FIG. 5 is illustrated in more detail. As described above, one transfer gate TG9 may be arranged to correspond to the photoelectric conversion element PD9, and the other transfer gate TG10 may be arranged to correspond to the photoelectric conversion element PD10.

FIG. 7B is a diagram for explaining characteristics of the photoelectric conversion elements (PD9, PD10) included in the fifth pixel group PG5, but the photoelectric conversion elements (PD9, PD10) shown in FIG. 7B are substantially the same as the photoelectric conversion elements (PD9, PD10) shown in FIG. 6B in terms of a fabrication process, a structure, and materials, and as such redundant description thereof will herein be omitted for brevity.

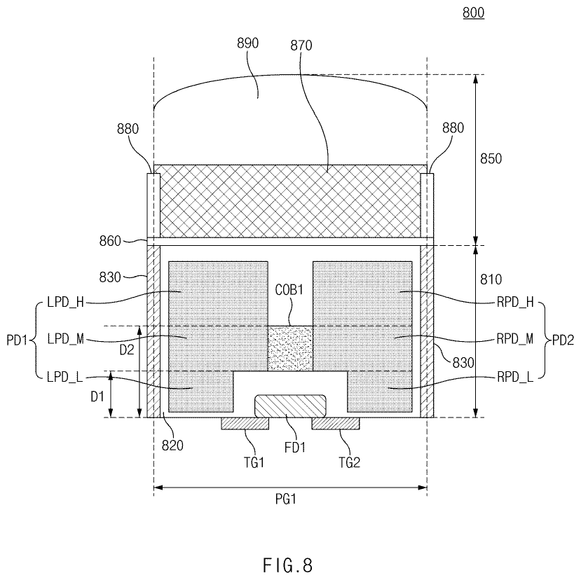

FIG. 8 is a cross-sectional view illustrating an example of the pixel groups shown in FIGS. 6A to 7B based on some implementations of the disclosed technology.

Referring to FIG. 8, a cross-sectional view of the corresponding pixel group taken along the first cutting line A-A′ of FIGS. 6B to 7B or the second cutting line B-B′ of FIGS. 6A and 6B is substantially the same as the cross-sectional view of the pixel group taken along the first cutting line A-A′ of FIG. 6A, and for convenience of explanation, a cross-section 800 of the first pixel group PG1 taken along the first cutting line A-A′ of FIG. 6A will hereinafter be described with reference to FIG. 8.

The cross-section 800 of the first pixel group PG1 may have a structure in which a substrate 810 and a light receiving layer 850 are vertically stacked.

The substrate 810 may include a top surface and a bottom surface facing away from each other. The bottom surface of the substrate 810 may be defined as a front side, and the top surface of the substrate 810 may be defined as a back side, without being limited thereto. For example, the substrate 810 may be a semiconductor substrate. For example, the substrate 810 may be a P-type or N-type bulk substrate, may be a substrate formed by growing a P-type or N-type epitaxial layer on the P-type bulk substrate, or may be a substrate formed by growing a P-type or N-type epitaxial layer on the N-type bulk substrate. The substrate 810 may include a silicon region 820.

The substrate 810 may include a first photoelectric conversion element PD1 and a second photoelectric conversion element PD2 that are spaced apart from each other, a first charge overflow barrier (COB1), a floating diffusion region FD1, and a device isolation structure 830.

Each of the first photoelectric conversion element PD1 and the second photoelectric conversion element PD2 may generate and accumulate photocharges in response to the intensity of incident light. The first photoelectric conversion element PD1 and the second photoelectric conversion element PD2 may be disposed in the substrate 810.

The first photoelectric conversion element PD1 may include impurity layers (LPD_H, LPD_M, LPD_L) formed at different depths using different ion implantation energies. The impurity layer (LPD_L) may be a layer formed at a depth equal to or less than a first depth D1 using the lowest ion implantation energy, the impurity layer (LPD_M) may be a layer formed at a depth from the first depth D1 to the second depth D2 using intermediate ion implantation energy, and the impurity layer (LPD_H) may be a layer formed at a depth equal to or greater than the second depth D2 using the highest ion implantation energy. Here, each of the first depth D1 and the second depth D2 may refer to the depth from the front surface of the substrate 810. The impurity layer LPD_L may be referred to as a first impurity layer, the impurity layer LPD_M may be referred to as a second impurity layer, and the impurity layer LPD_H may be referred to as a third impurity layer.

The second photoelectric conversion element PD2 may include impurity layers (RPD_H, RPD_M, RPD_L) formed at different depths using different ion implantation energies. The impurity layer (RPD_L) may be a layer formed at a depth equal to or less than the first depth D1 using the lowest ion implantation energy, the impurity layer (RPD_M) may be a layer formed at a depth from the first depth D1 to the second depth D2 using intermediate ion implantation energy, and the impurity layer (RPD_H) may be a layer formed at a depth equal to or greater than the second depth D2 using the highest ion implantation energy. The impurity layer RPD_L may be referred to as a fourth impurity layer, the impurity layer RPD_M may be referred to as a fifth impurity layer, and the impurity layer RPD_H may be referred to as a sixth impurity layer.

The first charge overflow barrier (COB1) may operate as a potential barrier between the first photoelectric conversion element PD1 and the second photoelectric conversion element PD2. The first charge overflow barrier (COB1) may be disposed between the first photoelectric conversion element PD1 and the second photoelectric conversion element PD2 so as to be in contact with each of the first photoelectric conversion element PD1 and the second photoelectric conversion element PD2. The first charge overflow barrier (COB1) may be formed simultaneously through a process in which the impurity layer (LPD_M) and the impurity layer (RPD_M) are formed, without being limited thereto.

The floating diffusion region FD1 may be arranged to contact the front surface of the substrate 810 at the center of the first pixel group PG1. The floating diffusion region FD1 may be spaced apart from each of the first photoelectric conversion element PD1, the second photoelectric conversion element PD2, and the first charge overflow barrier (COB1). The floating diffusion region FD1 may be formed by implanting impurities of a second conductivity type.

One side of the floating diffusion region FD1 may overlap the first transfer gate TG1, and the other side of the floating diffusion region FD1 may overlap the second transfer gate TG2.

A device isolation structure 830 may be disposed at a boundary between the first pixel group PG1 and another pixel group adjacent to the first pixel group PG1, and may be formed to be deeply etched in a vertical direction, so that the device isolation structure 830 may electrically or optically isolate the first pixel group PG1 and another pixel group from each other. The device isolation structure 830 may be formed as a frontside deep trench isolation (FDTI) structure or a backside deep trench isolation (BDTI) structure. An insulation layer (e.g., a silicon oxide layer, a silicon nitride layer, or the like) may be disposed in the device isolation structure 830. In some implementations, the insulation layer may include a polysilicon material to which a bias voltage for suppressing dark current can be applied.

The light receiving layer 850 may receive incident light from the outside of the image sensing device 100, and may transmit the received incident light to the substrate 810. The light receiving layer 850 may include an anti-reflection layer 860, an optical filter 870, one or more optical grid structures 880, and a microlens 890.

The anti-reflection layer 860 for reducing reflectivity of light incident upon the substrate 810 may be disposed over the substrate 810. The anti-reflection layer 860 may have a predetermined refractive index (e.g., a refractive index lower than that of the substrate 810) to reduce reflectivity.

The optical filter 870 may be disposed on the first photoelectric conversion element PD1 and the second photoelectric conversion element PD2 between adjacent optical grid structures 880. The optical filter 870 may selectively transmit light (e.g., red light, green light, blue light, magenta light, yellow light, cyan light, infrared (IR) light, or others) having a wavelength band to be transmitted. In this case, the transmission wavelength band may refer to a wavelength band of light to be selectively transmitted by the corresponding optical filter. For example, the optical filter 870 of the pixel group PG1 may selectively transmit green light. The optical filter 870 may include a colored photosensitive material corresponding to a specific color, or may include thin film layers that are alternately arranged.

The optical grid structures 880 may be disposed along a boundary between the first pixel group PG1 and another pixel group to minimize optical crosstalk between the pixel groups.

The microlenses 890 may be formed over the anti-reflection layer 860, the optical filters 870, and the optical grid structures 880, and may increase light gathering power of incident light, resulting in increased light reception (Rx) efficiency of the first photoelectric conversion element PD1 and the second photoelectric conversion element PD2.

FIGS. 9A and 9B are diagrams illustrating examples of functions of the charge overflow barrier (COB1) based on some implementations of the disclosed technology.

Referring to FIG. 9A, the function of the charge overflow barrier will hereinafter be described using the first charge overflow barrier (COB1) disposed between the first photoelectric conversion element PD1 and the second photoelectric conversion element PD2 as an example.

Each of the first photoelectric conversion element PD1 and the second photoelectric conversion element PD2 may have a potential well surrounded by a potential barrier, and the height of the potential barrier between the first photoelectric conversion element PD1 and the second photoelectric conversion element PD2 may be relatively low due to the first charge overflow barrier COB1.

When light is incident upon the first photoelectric conversion element PD1 and the second photoelectric conversion element PD2 in a state in which the first photoelectric conversion element PD1 and the second photoelectric conversion element PD2 are reset to have empty potential wells, each of the first photoelectric conversion element PD1 and the second photoelectric conversion element PD2 may generate and accumulate photocharges (see \textcircled{1} of FIG. 9A). In FIG. 9A, it is assumed that the speed at which the first photoelectric conversion element PD1 generates the first photocharge C1 is greater than the speed at which the second photoelectric conversion element PD2 generates the second photocharge C2.

The first photocharge C1 may continue to be generated and accumulated in the first photoelectric conversion element PD1 until exceeding the potential barrier caused by the first charge overflow barrier (COB1) (see \textcircled{2} of FIG. 9A).

The first photocharge C1 continues to be generated and accumulated in the first photoelectric conversion element PD1 while exceeding the potential barrier caused by the first charge overflow barrier (COB1). Then, the first photocharge C1 may move to the second photoelectric conversion element PD2 by passing through the first charge overflow barrier (COB1), and may be accumulated in the second photoelectric conversion element PD2. Thereafter, the first photocharge C1 and the second photocharge C2 may continue to accumulate in the second photoelectric conversion element PD2 until exceeding the potential barrier caused by the first charge overflow barrier (COB1) (see \textcircled{3} of FIG. 9A).

Subsequently, since the potential barrier by the first charge overflow barrier (COB1) is no longer functional, the third photocharge C3 additionally generated by the first photoelectric conversion element PD1 and the second photoelectric conversion element PD2 may be accumulated in an arbitrary device without distinction between the first photoelectric conversion element PD1 and the second photoelectric conversion element PD2. Thereafter, the third photocharge C3 may be accumulated until exceeding a potential barrier among the first photoelectric conversion element PD1, the second photoelectric conversion element PD2, and the outside (see \textcircled{4} of FIG. 9A).

Referring to FIG. 9B, there is a graph showing the relationship between the intensity of incident light and one or more signals. The one or more signals may include a signal (hereinafter referred to as “signal (SIG1) of the first photoelectric conversion element PD1”) caused by photocharges accumulated in the first photoelectric conversion element PD1, a signal (hereinafter referred to as “signal (SIG2) of the second photoelectric conversion element PD2”) caused by photocharges accumulated in the second photoelectric conversion element PD2, and a signal (SUM) corresponding to the sum of the signal (SIG1) of the first photoelectric conversion element PD1 and the signal (SIG2) of the second photoelectric conversion element PD2. The signal (SIG1) of the first photoelectric conversion element PD1 and the signal (SIG2) of the second photoelectric conversion element PD2 may be a basis of the pixel shift result. Additionally, the sum signal (SUM) of the signal (SIG1) of the first photoelectric conversion element PD1 and the signal (SIG2) of the second photoelectric conversion element PD2 may be a basis of color image data.

Since the first photoelectric conversion element PD1 generates and accumulates the first photocharge C1 and the second photoelectric conversion element PD2 generates and accumulates the second photocharge C2, each of the signal (SIG1) of the first photoelectric conversion element PD1 and the signal (SIG2) of the second photoelectric conversion element PD2 may increase with a predetermined slope as the intensity of incident light increases (see \textcircled{1} of FIG. 9B).

Until the first photocharge C1 is continuously generated and accumulated in the first photoelectric conversion element PD1 and then accumulated as much as the potential barrier caused by the first charge overflow barrier (COB1) (see \textcircled{2} of FIG. 9B), each of the signal (SIG1) of the first photoelectric conversion element PD1 and the signal (SIG2) of the second photoelectric conversion element PD2 may increase with a predetermined slope as the intensity of incident light increases.

The first photocharge C1 generated by exceeding the potential barrier caused by the first charge overflow barrier (COB1) moves to the second photoelectric conversion element PD2 after passing through the first charge overflow barrier (COB1) and is then accumulated in the second photoelectric conversion element PD2, such that the signal (SIG1) of the first photoelectric conversion element PD1 may remain unchanged and the signal (SIG2) of the second photoelectric conversion element PD2 may increase with a higher slope than the previous slope. The first photocharge C1 and the second photocharge C2 are continuously accumulated in the second photoelectric conversion element PD2 until being accumulated as much as the potential barrier caused by the first charge overflow barrier (COB1), such that the signal (SIG2) of the second photoelectric conversion element PD2 may continue to increase as the intensity of incident light increases (see \textcircled{3} of FIG. 9B).

Afterwards, the third photocharge C3 additionally generated by the first photoelectric conversion element PD1 and the second photoelectric conversion element PD2 may be accumulated until exceeding a potential barrier between each of the first and second photoelectric conversion element PD1 and PD2 and the outside, and the signal (SIG1) of the first photoelectric conversion element PD1 and the signal (SIG2) of the second photoelectric conversion element PD2 may increase with the same slope as the intensity of incident light increases (see \textcircled{4} of FIG. 9B).

A time section up to the position \textcircled{2} of FIG. 9B, which enables the signal (SIG1) of the first photoelectric conversion element PD1 to indicate the amount of the first photocharge C1 and enables the signal (SIG2) of the second photoelectric conversion element PD2 to indicate the amount of the second photocharge C2, may be defined as an autofocus (AF) enable function capable of detecting a phase difference using the signal (SIG1) of the first photoelectric conversion element PD1 and the signal (SIG2) of the second photoelectric conversion element PD2.

In addition, a time section up to the position \textcircled{4} of FIG. 9B, which enables the signal (SUM) of the sum of the signal (SIG1) of the first photoelectric conversion element PD1 and the signal (SIG2) of the second photoelectric conversion element PD2 to indicate the amount of photocharges generated by the first photoelectric conversion element PD1 and the second photoelectric conversion element PD2, may be defined as a full well capacity (FWC) section in which photocharges are accumulated within a FWC (full well capacity) of each of the first photoelectric conversion element PD1 and the second photoelectric conversion element PD2. In the FWC section (FWC), as the intensity of incident light increases, the sum signal (SUM) of the signal (SIG1) of the first photoelectric conversion element PD1 and the signal (SIG2) of the second photoelectric conversion element PD2 may increase linearly.

In a situation where the charge overflow barrier (COB1) is not present, if photocharges are accumulated in excess of the FWC of any one of the first photoelectric conversion element PD1 and the second photoelectric conversion element PD2, the linearity of the sum signal (SUM) of the signal (SIG1) of the first photoelectric conversion element PD1 and the signal (SIG2) of the second photoelectric conversion element PD2 cannot be maintained.

However, when the charge overflow barrier (COB1) is present as in the disclosed technology, even if photocharges are accumulated in excess of the FWC of any one of the first photoelectric conversion element PD1 and the second photoelectric conversion element PD2, the linearity of the sum signal (SUM) of the signal (SIG1) of the first photoelectric conversion element PD1 and the signal (SIG2) of the second photoelectric conversion element PD2 can be maintained, and thus a dynamic range can be expanded.

As is apparent from the above description, the disclosed technology may provide the image sensing device in which transfer gates included in each pixel group corresponding to one microlens are arranged symmetrically to each other with respect to the center of the pixel group, thereby guaranteeing symmetry between pixel groups affecting signal characteristics.

The embodiments of the disclosed technology may provide a variety of effects capable of being directly or indirectly recognized through the above-mentioned patent document.

Those skilled in the art will appreciate that the disclosed technology may be carried out in other specific ways than those set forth herein. In addition, claims that are not explicitly presented in the appended claims may be presented in combination as an embodiment or included as a new claim by a subsequent amendment after the application is filed.

Although a number of illustrative embodiments have been described, it should be understood that modifications and enhancements to the disclosed embodiments and other embodiments can be devised based on what is described and/or illustrated in this patent document.

What is claimed is:

1. An image sensing device comprising:
a first photoelectric conversion element configured to generate photocharges in response to an incident light and disposed to overlap a first region of a first microlens;
a second photoelectric conversion element configured to generate photocharges in response to the incident light and disposed to overlap a second region of the first microlens, wherein the first region and the second region are disposed along a first direction;
a first floating diffusion region located adjacent to the first photoelectric conversion element and the second photoelectric conversion element;
a first transfer gate disposed at a first side of the first floating diffusion region and configured to transfer the photocharges generated by the first photoelectric conversion element to the first floating diffusion region; and
a second transfer gate disposed at a second side of the first floating diffusion region and configured to transfer the photocharges generated by the second photoelectric conversion element to the first floating diffusion region, the second side being apart from the first side along the first direction and a second direction perpendicular to the first direction.

2. The image sensing device according to claim 1, wherein the first photoelectric conversion element is disposed in a substrate and includes:
a first impurity layer spaced apart from the first floating diffusion region by a first predetermined distance, and disposed at a first location having a depth less than or equal to a first depth from one surface of the substrate;
a second impurity layer configured to overlap the first floating diffusion region, and disposed at a second location having a depth from the first depth to a second depth greater than the first depth from the one surface of the substrate; and
a third impurity layer configured to overlap the first floating diffusion region, and disposed at a third location having a depth greater than or equal to the second depth from the one surface of the substrate.

3. The image sensing device according to claim 2, wherein the second photoelectric conversion element includes:
a fourth impurity layer spaced apart from the first floating diffusion region by a second predetermined distance, and disposed at a fourth location having the depth less than or equal to the first depth from the one surface of the substrate;
a fifth impurity layer configured to overlap the first floating diffusion region, and disposed at a fifth location having the depth from the first depth to the second depth from the one surface of the substrate; and
a sixth impurity layer configured to overlap the first floating diffusion region, and disposed at a sixth location having the depth greater than or equal to the second depth from the one surface of the substrate.

4. The image sensing device according to claim 3, further comprising:
a charge overflow barrier disposed between the second impurity layer and the fifth impurity layer.

5. The image sensing device according to claim 4, wherein:
the charge overflow barrier is disposed at a same depth as the second impurity layer and the fifth impurity layer.

6. The image sensing device according to claim 4, wherein:
the charge overflow barrier, the second impurity layer, and the fifth impurity layer are configured to include impurities of a same conductivity type.

7. The image sensing device according to claim 4, wherein:
the charge overflow barrier is configured to overlap the first floating diffusion region.

8. The image sensing device according to claim 1, further comprising:
a first additional transfer gate disposed at a bottom-left side of the first floating diffusion region and configured to transfer the photocharges generated by the first photoelectric conversion element to the first floating diffusion region; and
a second additional transfer gate disposed at a top-right side of the first floating diffusion region and configured to transfer the photocharges generated by the second photoelectric conversion element to the first floating diffusion region.

9. The image sensing device according to claim 8, wherein:
the first transfer gate and the first additional transfer gate are spaced apart from each other by a predetermined distance, are arranged to overlap the first photoelectric conversion element, and are electrically connected to each other.

10. The image sensing device according to claim 8, wherein:
the second transfer gate and the second additional transfer gate are spaced apart from each other by a predetermined distance, are arranged to overlap the second photoelectric conversion element, and are electrically connected to each other.

11. The image sensing device according to claim 1, further comprising:
a third photoelectric conversion element configured to overlap an upper region of a second microlens and configured to generate photocharges in response to the incident light;
a fourth photoelectric conversion element configured to overlap a lower region of the second microlens and configured to generate photocharges in response to the incident light;
a second floating diffusion region configured to accumulate photocharges received from at least one of the third photoelectric conversion element or the fourth photoelectric conversion element;
a third transfer gate disposed at the first side of the second floating diffusion region and configured to transfer photocharges of the third photoelectric conversion element to the second floating diffusion region; and
a fourth transfer gate disposed at the second side of the second floating diffusion region and configured to transfer photocharges of the fourth photoelectric conversion element to the second floating diffusion region.

12. The image sensing device according to claim 11, further comprising:
a signal line formed to extend in a row direction, and configured to overlap the first transfer gate and the third transfer gate to transmit a transfer signal for controlling the first transfer gate and the third transfer gate.

13. The image sensing device according to claim 11, further comprising:
a signal line formed to extend in a row direction, and configured to overlap the second transfer gate and the fourth transfer gate to transmit a transfer signal for controlling the second transfer gate and the fourth transfer gate.

14. The image sensing device according to claim 11, further comprising:
a third additional transfer gate disposed at a top-right side of the second floating diffusion region, and configured to transfer photocharges of the third photoelectric conversion element to the second floating diffusion region; and
a fourth additional transfer gate disposed at a bottom-left side of the second floating diffusion region, and configured to transfer photocharges of the fourth photoelectric conversion element to the second floating diffusion region.

15. The image sensing device according to claim 14, wherein:
the third transfer gate and the third additional transfer gate are spaced apart from each other by a predetermined distance, are arranged to overlap the third photoelectric conversion element, and are electrically connected to each other.

16. The image sensing device according to claim 14, wherein:
the fourth transfer gate and the fourth additional transfer gate are spaced apart from each other by a predetermined distance, are arranged to overlap the fourth photoelectric conversion element, and are electrically connected to each other.

17. The image sensing device according to claim 11, wherein:
a direction in which each of the first photoelectric conversion element and the second photoelectric conversion element extends is perpendicular to a direction in which each of the third photoelectric conversion element and the fourth photoelectric conversion element extends.

18. The image sensing device according to claim 11, wherein:
the first photoelectric conversion element, the second photoelectric conversion element, the third photoelectric conversion element, and the fourth photoelectric conversion element have a same size.

19. An image sensing device comprising:
a first pixel group configured to include a first microlens, a first photoelectric conversion element overlapping a left region of the first microlens and configured to convert light incident to the first photoelectric conversion element into photocharges, and a second photoelectric conversion element overlapping a right region of the first microlens and configured to convert light incident to the second photoelectric conversion element into photocharges, and a first transfer gate located at a first position with respect to a center of the first pixel group and configured to transfer the photocharges generated by the first photoelectric conversion element to a first floating diffusion region of the first pixel group; and
a second pixel group configured to include a second microlens, a third photoelectric conversion element overlapping an upper region of the second microlens and configured to convert light incident to the third photoelectric conversion element into photocharges, and a fourth photoelectric conversion element overlapping a lower region of the second microlens and configured to convert light incident to the fourth photoelectric conversion element into photocharges, and a second transfer gate located at the first position with respect to the center of the second pixel group and configured to transfer the photocharges generated by the third photoelectric conversion element to a second floating diffusion region of the second pixel group.

20. The image sensing device according to claim 19, wherein the first pixel group further includes a third transfer gate located at a second position with respect to the center of the first pixel group and configured to transfer the photocharges generated by the second photoelectric conversion element to the first floating diffusion region; and
wherein the second pixel group further includes a fourth transfer gate located at the second position with respect to the center of the second pixel group and configured to transfer photocharges generated by the fourth photoelectric conversion element to the second floating diffusion region.

21. The image sensing device according to claim 20, wherein:
the first transfer gate and the third transfer gate are arranged diagonally with respect to the center of the first pixel group; and
the second transfer gate and the fourth transfer gate are arranged diagonally with respect to the center of the second pixel group.

22. An image sensing device comprising:
a first photoelectric conversion element configured to generate photocharges in response to an incident light and disposed to overlap an upper region of a first microlens;
a second photoelectric conversion element configured to generate photocharges in response to the incident light and disposed to overlap a lower region of the first microlens;
a floating diffusion region configured to accumulate photocharges received from at least one of the first photoelectric conversion element or the second photoelectric conversion element;
a first transfer gate disposed at a top-left side of the floating diffusion region and configured to transfer the photocharges generated by the first photoelectric conversion element to the floating diffusion region; and
a second transfer gate disposed at a bottom-right side of the floating diffusion region and configured to transfer the photocharges generated by the second photoelectric conversion element to the floating diffusion region.
